(19) United States
(12) Patent Application Publication
(10) Pub. No.: US 2015/0255470 A1
(43) Pub. Date: Sep. 10, 2015

(54) SEMICONDUCTOR MEMORY DEVICE AND MANUFACTURING METHOD THEREOF

(71) Applicant: KABUSHIKI KAISHA TOSHIBA, Minato-ku (JP)

(72) Inventor: Tatsuya Okamoto, Inabe-Shi (JP)

(73) Assignee: KABUSHIKI KAISHA TOSHIBA, Minato-ku (JP)

(21) Appl. No.: 14/327,718

(22) Filed: Jul. 10, 2014

Related U.S. Application Data
(60) Provisional application No. 61/950,496, filed on Mar. 10, 2014.

(51) Int. Cl. H01L 27/115; H01L 21/3213; H01L 21/764

(52) U.S. Cl. CPC H01L 27/11517; H01L 21/764; H01L 21/32135

(57) ABSTRACT

In accordance with an embodiment, a semiconductor memory device includes a substrate and memory transistors on the substrate. The substrate has a semiconductor layer having impurity diffusion regions which become sources or drains. The memory transistors share the impurity diffusion regions.

Each of the memory transistors has a first insulating film on the substrate, a charge storage layer on the first insulating film, a second insulating film on the charge storage layer, and a control gate on the second insulating film. A bottom surface of the control gate is parallel to a top surface of the charge storage layer.

### CROSS REFERENCE TO RELATED APPLICATIONS

This application is based upon and claims the benefit of U.S. provisional Application No. 61/950,496, filed on Mar. 10, 2014, the entire contents of which are incorporated herein by reference.

### FIELD

Embodiments described herein relate generally to a semiconductor memory device and a manufacturing method thereof.

### BACKGROUND

In semiconductor memory devices, high integration and miniaturization of memory cells have been developed, and hence each distance between adjacent cells narrows. As a result, for example, in a floating gate type nonvolatile memory, capacity couplings increase, and in consequence, there sometimes occurs an adjacent cell interference that data written in a floating gate becomes a value different from an expected value under an influence of an adjacent cell.

Furthermore, as a result of the miniaturization, processing cannot be performed to a desirable depth in formation of shallow trench isolation (hereinafter abbreviated to “STI”), so that writing errors by punch-through sometimes occur.

### BRIEF DESCRIPTION OF THE DRAWINGS

In the accompanying drawings:

FIG. 1 is one example of a plan view schematically showing a part of a brief constitution of a cell array of a semiconductor memory device according to one embodiment;

FIG. 2 is one example of a sectional view cut along the D-D line of FIG. 1;

FIG. 3 is one example of a sectional view cut along the A-A line of FIG. 1;

FIG. 4 is one example of a sectional view cut along the B-B line of FIG. 1;

FIG. 5 is one example of a sectional view cut along the C-C line of FIG. 1; and

FIG. 6 to FIG. 12 are sectional views of exemplary steps to explain a manufacturing method of the semiconductor memory device according to one embodiment.

### DETAILED DESCRIPTION

In accordance with an embodiment, a semiconductor memory device includes a substrate and memory transistors on the substrate. The substrate has a semiconductor layer having impurity diffusion regions which become sources or drains. The memory transistors share the impurity diffusion regions.

Each of the memory transistors has a first insulating film on the substrate, a charge storage layer on the first insulating film, a second insulating film on the charge storage layer, and a control gate on the second insulating film. A bottom surface of the control gate is parallel to a top surface of the charge storage layer.

Embodiments will now be explained with reference to the accompanying drawings. Like components are provided with like reference signs throughout the drawings and repeated descriptions thereof are appropriately omitted. It is to be noted that the accompanying drawings illustrate the invention and assist in the understanding of the illustration and that the shapes, dimensions, and ratios and so on in each of the drawings may be different in some parts from those in an actual apparatus. For these differences, a skilled person could make proper modifications in design by reference to the following explanations and known arts.

(1) Semiconductor Memory Device

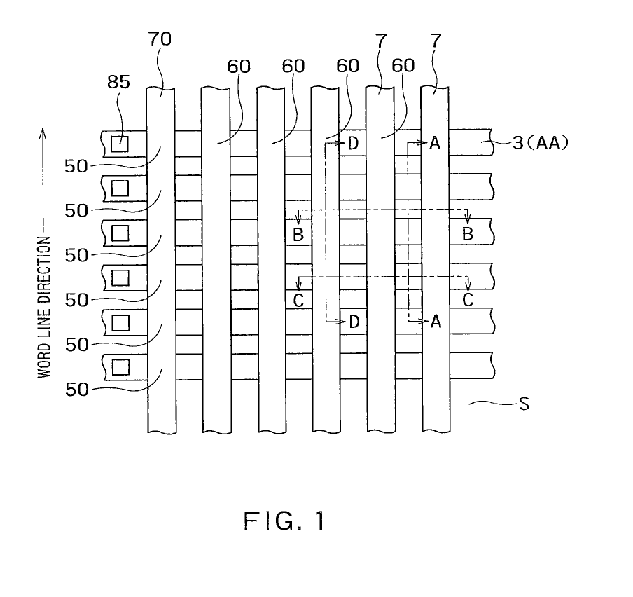

FIG. 1 is a plan view schematically showing a part of a brief constitution of a cell array of a semiconductor memory device according to one embodiment. In the present embodiment, a flat-cell type nonvolatile memory is picked up and described as an example.

As shown in FIG. 1, in each cell unit of the cell array, a selection transistor 50 is connected to one end side of each of a plurality of memory cells 60 connected in series, and in the same column, a plurality of NAND cell units are arrayed. The memory cells 60 of the same row which are arrayed adjacent to each other in a word line direction of the cell array are connected to common control gates (word lines) 7. The selection transistors 50 of the same row which are arrayed adjacent to each other in the word line direction of the cell array are connected to a common selection gate line 70. One end side (a drain) of each of the selection transistors 50 is connected to an unshown bit line via a bit line contact 85. In the present embodiment the word line direction corresponds to, for example, a second direction.

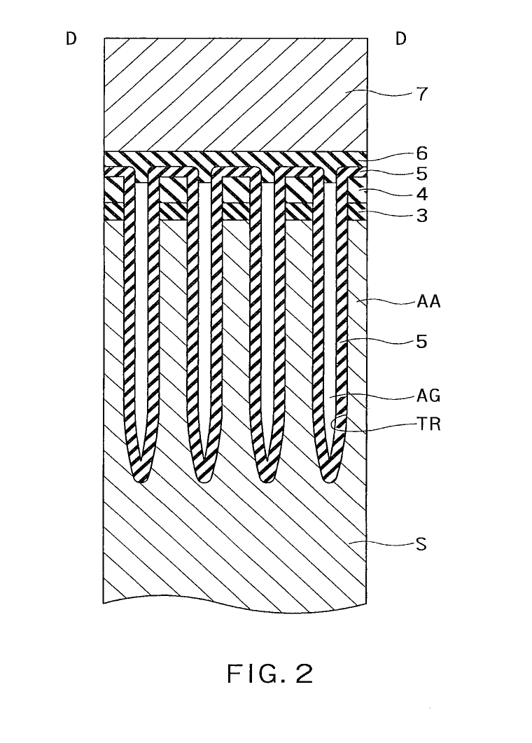

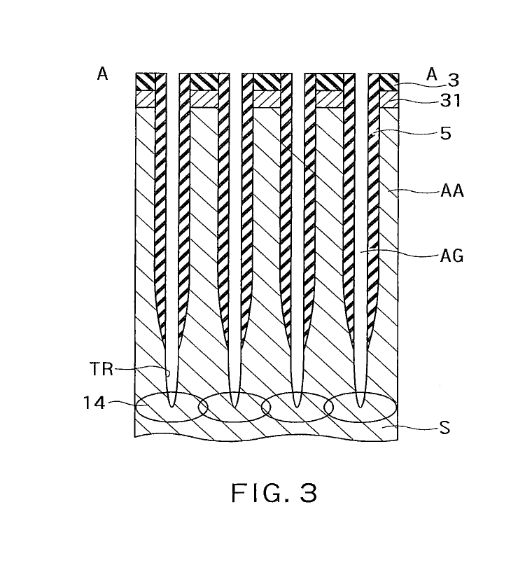

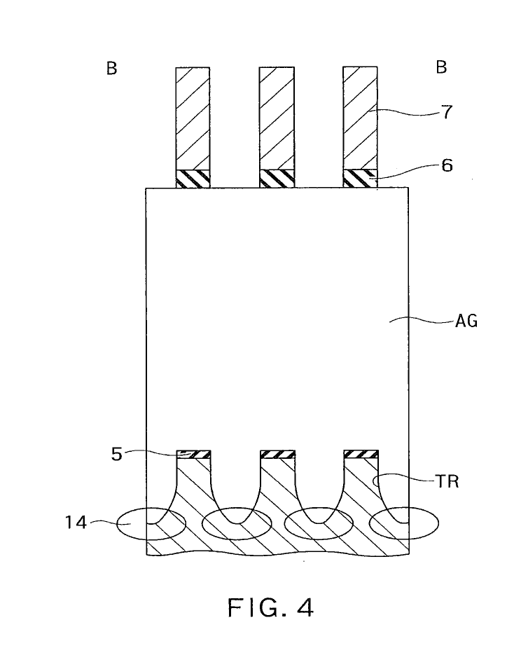

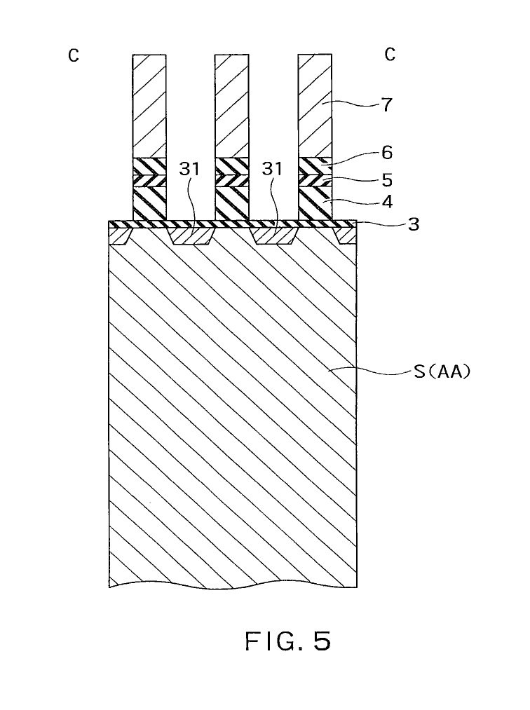

FIG. 2 is a sectional view cut along the D-D line of FIG. 1, and FIG. 3 is a sectional view cut along the A-A line of FIG. 1. Furthermore, FIG. 4 is a sectional view cut along the B-B line of FIG. 1, and FIG. 5 is a sectional view cut along the C-C line of FIG. 1.

As shown in FIG. 2, on an Si semiconductor substrate S of an active region AA defined by an element isolating trench TR (hereinafter simply referred to as “the trench TR”), a first insulating film 3 and a floating gate 4 as a charge storage layer including a high-k film are successively formed.

The first insulating film 3 functions as a tunnel insulating film.

The floating gate 4 is constituted of a laminate of a plurality of films having different dielectric constants, and an example thereof is a laminate of hafnium oxide (HfO₂) having a dielectric constant of 18, polysilicon (poly-Si) having a dielectric constant of 11.7, and the like. It is to be noted that the charge storage layer is not limited to the floating gate 4 described in the present embodiment, but it may be, for example, a charge storage layer constituted of a layer including a nitride film and the like.

A second insulating film 5 is formed so as to extend from a top surface of the floating gate 4 to an inner wall of the trench TR. The second insulating film 5 also functions as an inter-gate insulating film (between the floating gate 4 and the control gate 7). In FIG. 2 showing a region right under the control gate 7, the second insulating film 5 is formed so as to reach a bottom surface of each trench TR, but does not fill up the trench TR, with the result that an air gap AG is formed in the trench TR.

On the floating gate 4, a third insulating film 6 is formed via the second insulating film 5. The third insulating film 6 includes, for example, a low-k film.

The control gate 7 is formed on the third insulating film 6. A bottom surface of the control gate 7 is disposed in parallel with the top surface or a bottom surface of the floating gate 4, and does not have such a shape as to surround or cover the floating gate 4. In consequence, the semiconductor memory device of the present embodiment constitutes the flat-cell type nonvolatile memory.

Also in FIG. 3 showing a region between the control gates 7, the second insulating film 5 is formed on the inner wall of each trench TR, but does not fill up the trench TR, so that the air gap AG is formed in the trench TR. This respect is similar to the case of FIG. 2, but in FIG. 3, in each element isolating region, the trench TR is deeply formed so as to break through a bottom surface of the second insulating film 5, so that a substrate material of the semiconductor substrate S is exposed.

Furthermore, as shown by reference numeral 14 in FIG. 3, a profile of boron (B) is formed in a bottom portion of each trench TR. The boron (B) is diffused in this way, so that depletion can be inhibited to enable inhibition of punch-through, and it is possible to inhibit writing errors caused by a potential difference between the adjacent cells.

It is to be noted that in the active region AA between the control gates 7, the first insulating film 3 is formed on the silicon substrate S.

FIG. 4 is a sectional view cut along the B-B line of FIG. 1. Therefore, it is depicted as if the third insulating film 6 and the control gates 7 floated above the air gap AG.

Furthermore, as clarified by comparison of FIG. 2 with FIG. 3, a depth of each trench TR in the region right under the control gate 7 is different from that of each trench TR in the region between the control gates 7, and hence, on the bottom surfaces of the air gaps AGs, steps or concavities and convexities are formed so as to show a sectional shape of corrugation. In the region between the control gates 7, the profile of the boron (B) is formed in the bottom portion of the trench TR. In the present embodiment, the trench TR in the region between the control gates 7 corresponds to, e.g. a first element isolating trench.

It is to be noted that the second insulating film 5 is formed on the bottom surface of each trench TR in the region right under the control gate 7 (see FIG. 2). In the present embodiment, the trench TR in the region right under the control gates 7 corresponds to, e.g. a second element isolating trench.

As shown in FIG. 5, in the active region AA perpendicular to the word line direction, the first insulating film 3 is formed on the whole surface of the silicon substrate S, and on the first insulating film, the floating gate 4, the second insulating film 5, the third insulating film 6 and the control gate 7 are formed. On a surface layer of the semiconductor substrate S in the region between the control gates 7, there is formed an impurity diffusion region 31 which becomes a source or a drain.

In the present embodiment, there has been described the example where the silicon substrate S is used as the substrate, but the present invention should not be limited to this example. Therefore, in addition to a semiconductor substrate of a material other than Si, a glass substrate or a ceramic substrate can also be used, as long as its surface layer includes a semiconductor layer in which a channel of a cell transistor can be formed.

According to the semiconductor memory device of at least one embodiment described above, the control gate disposed in parallel with the top surface or the bottom surface of the floating gate is included, and the air gap AG is formed in each element isolating trench. Therefore, there is provided the flat-cell type nonvolatile memory in which interference between the cells is inhibited.

Furthermore, according to the semiconductor memory device of the at least one embodiment described above, the profile of the boron (B) is formed in each trench bottom portion in which the substrate material is exposed. In consequence, the depletion can be inhibited to enable the inhibition of the punch-through, and it is possible to inhibit the writing errors caused by the potential difference between the adjacent cells.

(2) Manufacturing Method of Semiconductor Memory Device

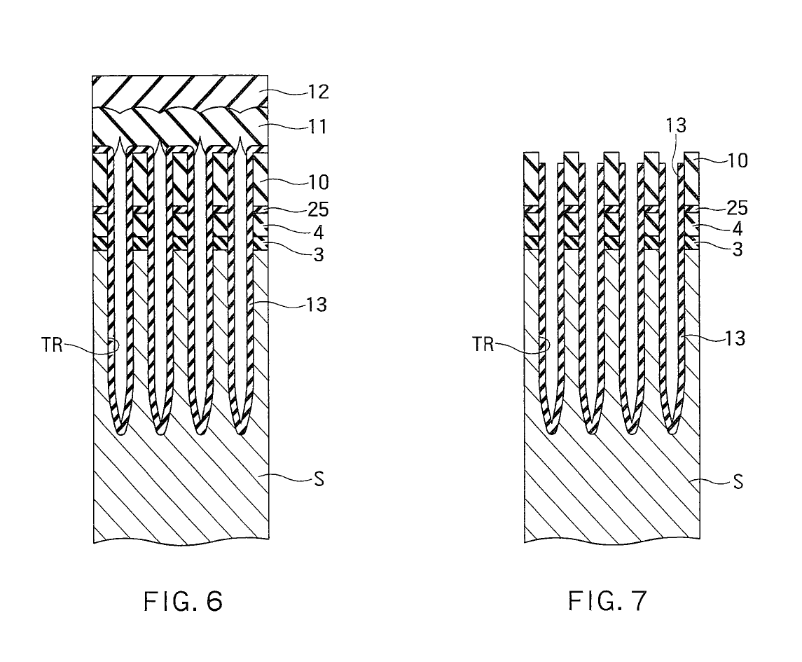

Next, a manufacturing method of the semiconductor memory device shown in FIG. 1 to FIG. 5 will be described with reference to FIG. 6 to FIG. 12. Each of FIG. 6 to FIG. 12 is an example of a step sectional view cut along the D-D line of FIG. 1.

First, on the silicon substrate S, the first insulating film 3, the floating gate 4 including the high-k film, and a protective film 25 are successively formed, and on the protective film 25, a silicon nitride film 10 is formed by patterning in which a resist is used. The floating gate 4 is formed by laminating a plurality of films having different dielectric constants, for example, films made of hafnium oxide (HfO₂) having a dielectric constant of 18, films made of polysilicon (poly-Si) having a dielectric constant of 11.7, or the like.

Next, the protective film 25, the floating gate 4, the first insulating film 3 and the surface layer of the silicon substrate S are selectively removed by etching in which the silicon nitride film 10 is used as a mask and a halogen gas of fluorine (F), chlorine (Cl) or the like is used, whereby the trench TR is formed in each element isolating region.

Next, on the whole surface of each trench TR, a silicon oxide film is formed as an inner wall protective film 13 for each trench TR, and then an interlayer insulating film 11 having a poor coverage is formed by plasma CVD (chemical vapor deposition) in which, for example, P—SiH₄ is used. Owing to anisotropy in the plasma CVD, it is avoided that the interlayer insulating film 11 is buried in the trench TR. In this way, an opening of the trench TR is covered, and then a cap material 12 is formed on the whole surface as shown in FIG. 6.

The cap material 12 protects a memory cell region from processing of another element region of a peripheral transistor or the like. Furthermore, the nitride film 10 functions as a stopper film in the next chemical mechanical polishing (CMP) step.

Next, the CMP is carried out, so that the cap material 12 and the interlayer insulating film 11 are removed until the top surface of the nitride film 10 is exposed, and then a top portion of the silicon oxide film 13 is selectively removed as shown in FIG. 7 by wet or dry etching of a high selectivity.

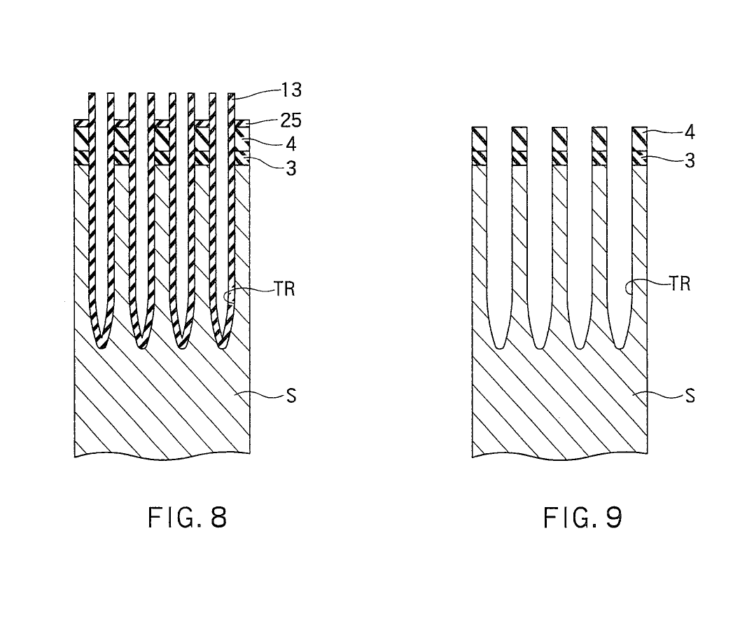

Next, as shown in FIG. 8, the silicon nitride film 10 only is selectively removed by a heat phosphoric acid treatment or the like.

Subsequently, as shown in FIG. 9, the inner wall protective film 13 of each trench TR is removed together with the protective film 25 by a dilute hydrofluoric acid treatment or the like in which, for example, buffered hydrofluoric acid (buffered HF) obtained by mixing ammonium (NH₄), hydrogen fluoride (HF) and water (H₂O) is used.

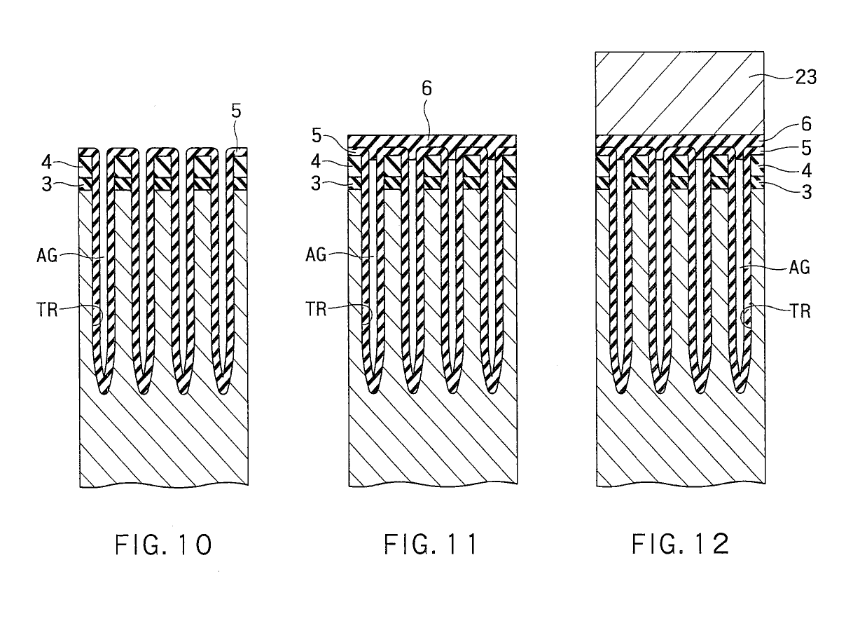

Next, a silicon oxide film is formed on the whole surface, to form the second insulating film 5 as shown in FIG. 10. A film thickness of the second insulating film 5 is regulated in consideration of the coverage of the high-k film 6 in such a manner that the high-k film 6 to be formed in the next step does not enter the trenches TRs.

Next, as shown in FIG. 11, the high-k film 6 having a poor coverage is formed to form the air gap AG in each trench TR.

Subsequently, as shown in FIG. 12, a film of a metal material 23 is formed on the whole surface, and then an unshown resist is formed. Afterward, the metal material 23 is processed by dry etching to form the control gates (the word lines) 7. In consequence, there is provided the flat-cell type nonvolatile memory shown in FIG. 1 to FIG. 5.

During the processing of the metal material 23, as shown in FIG. 12, the high-k film 6 and the metal material 23 are laminated above the trenches TRs, but the floating gates 4 are not formed. Therefore, during the processing of the metal material 23, the floating gates 4 are removed in the active region AA, and in the element isolating region, the second insulating film 5 in the bottom portion of each trench TR is pierced to remove a part of the silicon substrate S. Thus, as shown in FIG. 3, the bottom surface of each trench TR is deeper as much as the removed portion.

Furthermore, each of the floating gates 4 includes the high-k film, and hence a chlorine gas including boron (B) is used to process the metal material 23. In consequence, as shown in FIG. 3 and FIG. 4, the profile of the boron (B) is formed in the bottom portion of each trench TR by self-alignment.

It is to be noted that instead of using the chlorine gas including the boron (B), the profile of the boron (B) can be formed by implantation.

By the etching for the processing of the metal material 23, the bottom surface of the trench TR deepens only in the region between gate electrodes. Therefore, as shown in FIG. 4, steps are generated right under the gate electrodes 7, but the profiles of the boron (B) are formed, and hence any problems do not occur in an operation of the device.

According to the manufacturing method of the semiconductor memory device of at least one embodiment described above, the second insulating film is formed so as to extend from the top surface of the floating gate to the inner wall of the trench, and a film of an electrode material which becomes the gate electrode is formed on the floating gate via the third insulating film on the second insulating film. Furthermore, the film thickness of the second insulating film is regulated so as to form the air gap in the trench. In consequence, it is possible to manufacture the flat-cell type nonvolatile memory in which the interference between the cells is inhibited by an air gap structure.

Furthermore, according to the manufacturing method of the semiconductor memory device of the at least one embodiment described above, the second insulating film in the bottom portion of each trench is removed by the etching for the processing of the gate electrodes, to dig the trench downward in such a manner that the semiconductor layer right under the bottom portion of the trench is exposed. Thus, the trench having a desirable depth can be formed.

Furthermore, according to the manufacturing method of the semiconductor memory device of the at least one embodiment described above, the profile of the boron (B) is formed in the bottom portion of each trench by the self-alignment, and hence the depletion can be inhibited to enable the inhibition of the punch-through. In consequence, there is provided the nonvolatile memory in which the writing errors caused by the potential difference between the adjacent cells are inhibited.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor memory device comprising:
a substrate comprising a semiconductor layer comprising impurity diffusion regions which become sources or drains; and
memory transistors, on the substrate, which share the impurity diffusion regions,
wherein each of the memory transistors comprises a first insulating film on the substrate, a charge storage layer on the first insulating film, a second insulating film on the charge storage layer, and a control gate on the second insulating film, and
a bottom surface of the control gate is parallel to a top surface of the charge storage layer.

2. The device of claim 1,
wherein element isolating trenches defining the impurity diffusion regions are disposed in the substrate, and each of the trenches are provided with an air gap.

3. The device of claim 2,
wherein the second insulating film extends from the top surface of the charge storage layer to an inner wall of the trench.

4. The device of claim 3,
wherein the semiconductor layer is exposed in a part of a bottom surface of the trench.

5. The device of claim 4,
wherein the semiconductor layer is exposed in a part of the bottom surface of the trench in each region between the control gates, and comprises boron (B) diffused in the exposed surface.

6. The device of claim 2,
wherein each of the element isolating trenches is disposed so as to extend in a first direction, and
each of the control gates is arranged so as to extend in a second direction intersecting the first direction.

7. The device of claim 6,
wherein the element isolating trenches comprises a first element isolating trench located between the gate electrodes and a second element isolating trench located under the gate electrodes,
the bottom portion of the first element isolating trench is deeper than the bottom portion of the second element isolating trench, and
the bottom portion of the first element isolating trench is covered with no insulating film.

8. The device of claim 2,
wherein the bottom surfaces of the trenches comprise a concave and convex shape.

9. The device of claim 3,
wherein the bottom surfaces of the trenches comprise a concave and convex shape, and
the semiconductor layer is exposed in the bottom surface of the trench in the concave shape.

10. The device of claim 2,
wherein the charge storage layer comprises a plurality of films having different dielectric constants.

11. A manufacturing method of a semiconductor memory device, the method comprising:
forming a first insulating film on a semiconductor layer;
forming a charge storage layer on the first insulating film;
forming a trench in the semiconductor layer by selectively removing the first insulating film, the charge storage layer and the semiconductor layer;
forming a second insulating film on a top surface of the charge storage layer and an inner wall of the trench;
forming a third insulating film above the second insulating film and above the trench;
depositing an electrode material on the third insulating film, and
patterning the electrode material to form a gate electrode.

12. The method of claim 11,
wherein the trench is not completely filled by the third insulating film.

13. The method of claim 11,
wherein a thickness of the second insulating film is regulated in such a manner that an air gap is formed in the trench.

14. The method of claim 11,
wherein the trench is formed so as to extend in a first direction, and
the electrode material is patterned in such a manner that the gate electrode extends in a second direction intersecting the first direction.

15. The method of claim 14,
wherein the patterning the electrode material comprises removing part of the bottom of the second insulating film, thereby making the trench between the gate electrodes deeper than the trench under the gate electrodes, and exposing the semiconductor layer in the bottom of the trench between the gate electrodes.

16. The method of claim 11,
wherein a chlorine-based gas including boron (B) is used in patterning the electrode material.

17. The method of claim 11 further comprising implanting boron (B) into the bottom of the trench between the gate electrodes.

18. The method of claim 11,
wherein the forming of the charge storage layer comprises successively forming a plurality of films having different dielectric constants.
